(19) United States
(12) Patent Application Publication
(10) Pub. No.: US 2026/0206542 A1
(43) Pub. Date: Jul. 16, 2026

(54) METHOD FOR MONITORING WORD LINE

(71) Applicant: Winbond Electronics Corp., Taichung City (TW)

(72) Inventor: Chih-Yu Chiang, Tainan City (TW)

(73) Assignee: Winbond Electronics Corp., Taichung City (TW)

(21) Appl. No.: 19/369,343

(22) Filed: Oct. 27, 2025

(30) Foreign Application Priority Data
Nov. 26, 2024 (TW) 113145492

(51) Int. Cl. H10P 74/20; G01N 23/04; H10P 74/00

(52) U.S. Cl. CPC H10P 74/203; G01N 23/04; H10P 74/235; G01N 2223/102; G01N 2223/303; G01N 2223/6116

(57) ABSTRACT

A method for monitoring a word line includes the following steps. A depth index (DI) about a word line depth calculated by Equation (1) is provided. Electron beam scanning is performed on a first wafer, and multiple first DIs are obtained according to a predetermined θ, SP and W of each of multiple scanned first word lines, and Equation (1). Multiple actual depths of the first word lines are obtained. An R² value of the first DIs and the actual depths is calculated via regression analysis, and the R² value is confirmed to be not less than 0.9. The electron beam scanning is performed on a second wafer, and multiple second DIs are obtained. A 3-sigma (3σ) of the second DIs is calculated, and uniformity of word line depths of the second wafer is monitored according to the 3-sigma.

DI=tan(θ)×(SP−W)/2 Equation (1)

### CROSS-REFERENCE TO RELATED APPLICATION

This application claims the priority benefit of Taiwan application serial no. 113145492, filed on Nov. 26, 2024. The entirety of the above-mentioned patent application is hereby incorporated by reference herein and made a part of this specification.

### BACKGROUND

### Technical Field

The disclosure relates to a method for monitoring a semiconductor element, and in particular to a method for monitoring a word line.

### Description of Related Art

In the current semiconductor manufacturing processes, a buried word line is formed in a substrate, and the method for forming it may include the following steps. First, multiple trenches are formed in the substrate. Then, a word line material layer is formed on the substrate to fill the trenches. After that, an etch back process is performed to remove the word line material layer on the substrate surface and a part of the word line material layer in the trenches.

For the word line material layers located in different trenches, the degree of etching may vary, resulting in difference in the distance from the top surface of each word line to the top plane of the trench (referred to as a word line depth in the disclosure). In addition, in general, the extension direction of the formed word line intersects with that of an active region, so the word line extends on the active region and an isolation structure. Therefore, different parts of the same word line also have different word line depths. Poor uniformity of the word line depths seriously affects the electrical performance of the semiconductor element.

In order to monitor the word line depth, a transmission electron microscope (TEM) is most commonly used for directly detect, which results in wafer damage and excessive detection time. In addition, since TEM inspection take too long, the production line must be halted, causing reduced production capacity.

Therefore, how to effectively monitor the word line depth without excessive time consumption or impact on production capacity is currently one of the key issues.

### SUMMARY

The disclosure provides a method for monitoring a word line that allows for real-time and rapid assessment of their depth and depth.

A method for monitoring a word line of the disclosure is used to monitor depth uniformity of multiple word lines located in multiple trenches in a substrate and includes the following steps. A depth index about a word line depth is provided. The depth index represents a distance from a top surface of the word line to a top of the trench and is calculated by Equation (1). The trench has an inclined sidewall, θ is an included angle between the inclined sidewall of the trench and a top plane of the trench, SP is a width of the top of the trench, W is a width of the top surface of the word line, and DI is the depth index. Electron beam scanning is performed on a first wafer, and multiple first DIs are obtained according to a predetermined θ, SP and W of each of multiple first word lines in a local region of the first wafer, and Equation (1). Multiple actual depths of the first word lines in the local region are obtained. An R² value of the first DIs and the actual depths is calculated via regression analysis, and the R² value is confirmed to be not less than 0.9. The electron beam scanning is performed on a second wafer, and multiple second DIs are obtained according to the predetermined θ, SP and W of each of multiple second word lines in a local region of the second wafer, and Equation (1). A 3-sigma (3σ) of the second DIs is calculated, and uniformity of word line depths of the second wafer is monitored according to the 3-sigma.

DI=tan(Θ)×(SP−W)/2 Equation (1)

Based on the above, in the method for monitoring the word line of the disclosure, multiple depth indexes may be obtained via performing electron beam scanning on the second wafer and Equation (1) above, and whether the word line depths of the second wafer meet a uniformity requirement is determined according to the 3-sigma of the depth indexes. In this way, uniformity of the word line depths may be monitored without the need to perform destructive scanning on the second wafer and without stopping a production line. Therefore, detection time may be effectively saved without excessive wafer consumption.

### BRIEF DESCRIPTION OF THE DRAWINGS

FIG. 1 is a flowchart of a method for monitoring a word line according to a first embodiment of the disclosure.

FIG. 2 is a schematic cross-sectional view of a word line located in a trench according to the first embodiment of the disclosure.

FIG. 3 is a result after performing regional positioning processing on an image of a first wafer in the first embodiment of the disclosure.

FIG. 4 is a flowchart of a method for monitoring a word line according to a second embodiment of the disclosure.

### DESCRIPTION OF THE EMBODIMENTS

In a semiconductor manufacturing process, during the formation of buried word lines, an etch back process may cause word lines located in different trenches having different word line depths, and different parts of the same word line may also have different word line depths. Therefore, a method is needed to monitor depths and depth uniformity of word lines, while minimizing wafer usage and detection time, and without significantly impacting production capacity.

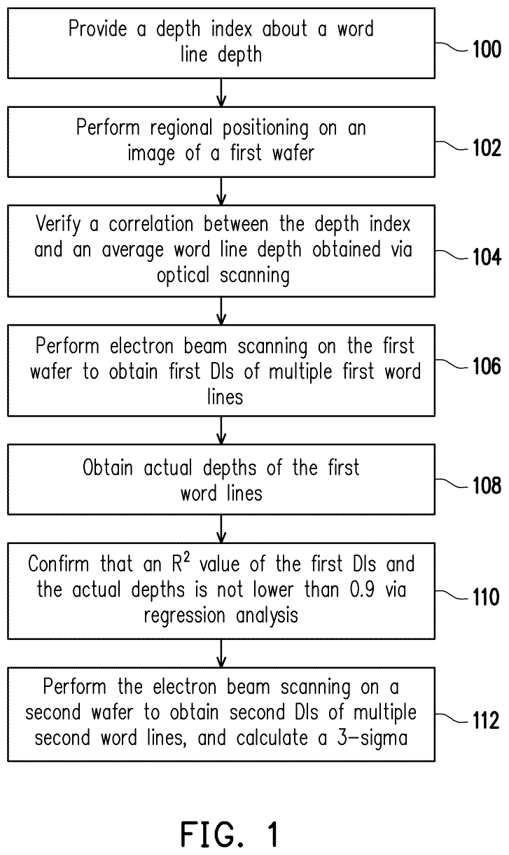

FIG. 1 is a flowchart of a method for monitoring a word line of the disclosure. In the embodiment, a first wafer may be any wafer in a batch of wafers in a semiconductor production line, and a second wafer may be another wafer from that batch. Therefore, the first and the second wafers are fabricated in the same batch and possess identical predetermined structure. In the embodiment, the predetermined structure is a word line formed in a trench. In addition, the trench has an inclined sidewall, and an angle θ is defined between the inclined sidewall and a top plane of the trench.

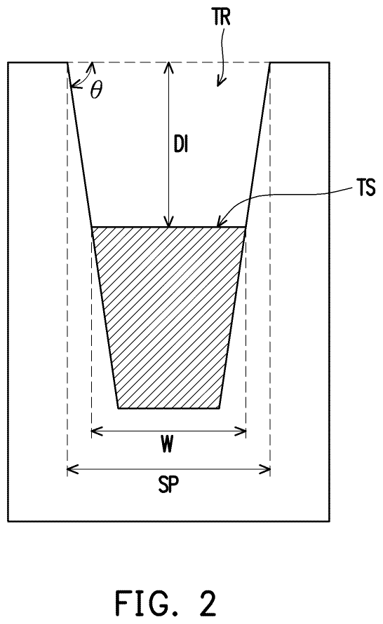

First, in step 100, a depth index related to the depth of the word line is provided. In the embodiment, as shown in FIG. 2, a depth index DI represents a distance from a top surface TS of a word line WL located in a trench TR to a top of the trench TR. In addition, the top of the trench TR has a width SP, and the top surface TS of the word line WL has a width W. In the embodiment, the depth index DI may be calculated using Equation (1) below.

DI=tan(Θ)×(SP−W)/2 Equation (1)

In the embodiment, the width SP of the top of the trench TR and the width W of the top surface TS of the word line WL may be obtained by electron beam scanning. Specifically, an electron beam inspection equipment (e.g., PROVision® 3E by Applied Materials) may be used to perform electron beam scanning, and the width SP and the width W may be obtained by reading signal sources at different positions under the same voltage (e.g., 25 kV).

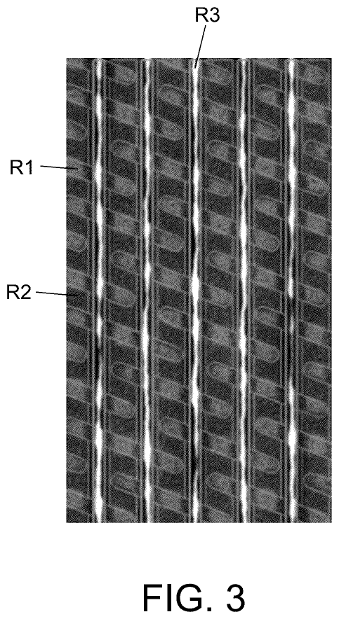

Next, in step 102, regional positioning processing is performed on an image of the first wafer from the batch of wafers to define multiple active regions, isolation structure regions, and multiple word line regions corresponding to first word lines. For example, in the embodiment, a voltage contrast scan may be performed on the first wafer to obtain a grayscale image, as shown in FIG. 3. Next, as shown in FIG. 3, the boundary of the active region in the image is clearly marked to define an active region R1 and an isolation structure region R2, and the boundary of the word line in the image is clearly marked to define a word line region R3. The disclosure does not limit the methods of regional positioning processing, as long as the active region R1, the isolation structure region R2, and the word line region R3 may be clearly defined.

After defining the active region R1, the isolation structure region R2, and the word line region R3, a region where the word line region R3 overlaps with the active region R1 is defined as a first region, and a region where the word line region R3 overlaps with the isolation structure region R2 is defined as a second region. For the same word line, since the depth of the part located on the active region R1 is different from that of the part located on the isolation structure region R2, these two parts need to be distinguished.

Then, in step 104, Equation (1) is verified to confirm that, for the word line at different depths, there is a strong correlation between the depth index DI obtained via electron beam scanning and according to Equation (1) and an average word line depth obtained via optical scanning.

In detail, in step 104, a first test wafer, a second test wafer, and a third test wafer are provided. The word line depths of the first, second, and third test wafers are different from each other. For example, when the first, second, and third test wafers are measured using optical critical dimension (OCD) measurement technology, the average word line depth of the first test wafer may be 75 nm, that of the second test wafer may be 85 nm, and that of the third test wafer may be 95 nm. In addition, by respectively performing electron beam scanning on the first, second, and third test wafers, multiple test depth indexes (DIs) may be obtained for the first test wafer, the second test wafer, and the third test wafer, respectively. Then, through regression analysis, an R² value of the test DIs and average depths of the first test wafer, the test DIs and average depths of the second test wafer, and the test DIs and average depths of the third test wafer is calculated to be approximately 0.983, and the R² value is confirmed to be not lower than 0.9. Therefore, for different word line depths, it may be verified that the depth index DI obtained via electron beam scanning and calculated according to Equation (1) exhibits a strong correlation with the average word line depth obtained via optical scanning.

Next, in step 106, the electron beam scanning is performed on the first wafer, and multiple first DIs are obtained according to a predetermined θ, SP and W of each of the first word lines in a local region of the scanned first wafer, and Equation (1).

Specifically, in the embodiment, the predetermined θ may be the included angle θ of the trenches of the previous batch of wafers, or the included angle θ obtained by scanning the first wafer using OCD measurement technology in advance, which is not limited in the disclosure. Since the trenches where the word lines on the same wafer are located generally have the same profile, the trenches have the same included angle θ. After performing electron beam scanning on the first wafer, multiple first depth indexes DI are obtained based on the predetermined θ, SP and W of each first word line of the scanned first wafer, and Equation (1). For example, after performing electron beam scanning on the first wafer, the respective first depth indexes DI of 4 first word lines located on the active region R1 and the respective first depth indexes DI of 3 first word lines located on the isolation structure region R2 may be obtained, wherein the first depth indexes DI of the 4 first word lines located on the active region R1 are respectively 88.1 nm, 81.2 nm, 82.4 nm, and 89.6 nm, and the first depth indexes DI of the 3 first word lines located on the isolation structure region R2 are respectively 75.5 nm, 90.2 nm, and 78.9 nm.

Then, in step 108, actual depths of the first word lines of the first wafer are obtained.

Specifically, in the embodiment, a TEM may be used to obtain the actual depths of the first word lines of the first wafer. For example, for the 7 first word lines, the actual depths of the 4 first word lines located on the active region R1 are respectively 87 nm, 80 nm, 83 nm, and 89 nm, and the actual depths of the 3 first word lines located on the isolation structure region R2 are respectively 74 nm, 89 nm, and 80 nm.

Next, in step 110, regression analysis is performed on the first depth indexes DI obtained in step 106 and the actual depths obtained in step 108 to obtain the R² value, and it is confirmed that the R² value is not less than 0.9. In this way, it may be confirmed that the depth index DI obtained via electron beam scanning and according to Equation (1) exhibits a strong correlation with the actual word line depth.

For example, in the embodiment, regression analysis shows that the R² value of the first depth indexes DI and the actual depths of the first word lines located on the active region R1 is 0.96. Therefore, it may be confirmed that there is a strong correlation between the first depth indexes DI and the actual depths of the first word lines located on the active region R1. In addition, regression analysis shows that the R² value of the first depth indexes DI and the actual depths of the first word lines located on the isolation structure region R2 is 0.97. Therefore, it may be confirmed that there is a strong correlation between the first depth indexes DI and the actual depths of the first word lines located on the isolation structure region R2.

Step 104 to step 110 above may be regarded as two verifications performed on Equation (1) to confirm that for various word line depths, there is a strong correlation between the first depth indexes DI and the actual depths of the first word lines in the first wafer.

After that, in step 112, the electron beam scanning is performed on the second wafer among the same batch of wafers, and multiple second depth indexes DI are obtained according to the predetermined θ, SP and W of each of multiple second word lines in a local region of the second wafer, and Equation (1). Since the trenches where the word lines on the same batch of wafers are located basically have the same outline, the trenches on different wafers basically have the same included angle θ.

In addition, after obtaining the second depth indexes DI, a 3-sigma of the second depth indexes DI is calculated, and uniformity of word line depths of the second wafer is monitored according to the 3-sigma.

In other words, in the embodiment, whether the word line depths of the second wafer meet a uniformity requirement may be instantly and directly determined via performing electron beam scanning on the second wafer and calculating the 3-sigma. For example, when the obtained 3-sigma is closer to 0, it means that uniformity of the word line depths of the second wafer is better. When the obtained 3-sigma is too large, it means that uniformity of the word line depths of the second wafer is poor, and the process may need to be adjusted.

In addition, in the embodiment, uniformity of the word line depths may be monitored without the need to perform destructive scanning on the second wafer, and detection may be performed without stopping the production line. Therefore, detection time is effectively saved without excessive wafer consumption.

In addition, in the disclosure, in addition to instantly and directly determining whether the word line depths of the wafer meet the uniformity requirement according to the 3-sigma, whether the actual depths meet the requirement may also be monitored according to the depth indexes, which will be explained below.

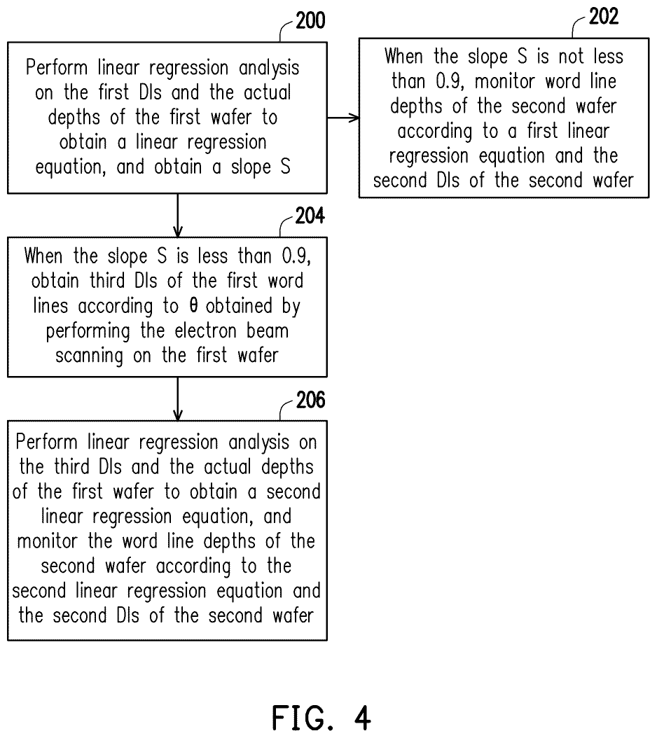

FIG. 4 is a flowchart of a method for monitoring a word line according to a second embodiment of the disclosure.

Please refer to FIG. 4. In step 200, after verifying Equation (1) and obtaining the first depth indexes DI and the actual depths of the first word lines of the first wafer, that is, after step 110, linear regression analysis is performed on the first depth indexes DI and the actual depths of the first wafer to obtain a slope S.

For example, in the embodiment, by performing linear regression analysis on the first depth indexes DI and the actual depths of the first word lines located on the active region R1, a linear regression equation of Equation (2) may be obtained, wherein the slope S is 0.953 (greater than 0.9). In addition, by performing linear regression analysis on the first depth indexes DI and the actual depths of the first word lines located on the isolation structure region R2, a linear regression equation of Equation (3) may be obtained, wherein the slope S is 0.9641 (greater than 0.9).

Y=3.435+0.953X Equation (2)

Y=2.39+0.9641x Equation (3)

Since the slopes S of Equation (2) and Equation (3) are both greater than 0.9 (close to 1), it means that the depth index obtained via Equation (1) may accurately reflect the actual depth, that is, there is a very small deviation between the depth index and the actual depth. In this way, the actual depths of the second word lines may be monitored via the linear regression equations (Equation (2) and Equation (3)) and the second depth indexes D2 of the second wafer without the need to perform destructive scanning on the second wafer to obtain the actual depths.

In addition, in step 202, when the slope S obtained by performing linear regression analysis on the first depth indexes DI and the actual depths of the first word lines is less than 0.9, it means that there is a large deviation between the depth indexes and the actual depths. At this time, the predetermined θ in step 106 is replaced with θ obtained by performing electron beam scanning on the first wafer, and multiple third depth indexes DI are obtained according to Equation (1). Then, similar to step 200, linear regression analysis is performed on the third depth indexes DI and the actual depths to obtain a new linear regression equation, and the actual depths of the word lines of the second wafer may be monitored according to the new linear regression equation and the second depth indexes DI of the second wafer.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A method for monitoring a word line, used to monitor depth uniformity of a plurality of word lines located in a plurality of trenches in a substrate, the method for monitoring the word line comprising:
providing a depth index about a word line depth, wherein the depth index represents a distance from a top surface of the word line to a top of the trench and is calculated by Equation (1),
DI=tan(Θ)×(SP−W)/2 Equation (1),
wherein the trench has an inclined sidewall, an angle θ is defined between the inclined sidewall of the trench and a top plane of the trench, SP is a width of the top of the trench, W is a width of the top surface of the word line, and DI is the depth index;
performing electron beam scanning on the first wafer, and obtaining a plurality of first depth indexes (DIs) according to a predetermined θ, SP and W of each of a plurality of first word lines in a local region of the scanned first wafer, and Equation (1);
obtaining a plurality of actual depths of the first word lines in the local region;
calculating an R² value of the first DIs and the actual depths via regression analysis, and confirming that the R² value is not less than 0.9;
performing the electron beam scanning on the second wafer, and obtaining a plurality of second DIs according to the predetermined θ, SP and W of each of a plurality of second word lines in a local region of the second wafer, and Equation (1); and
calculating a 3-sigma of the second DIs, and monitoring uniformity of word line depths of the second wafer according to the 3-sigma.

2. The method for monitoring the word line according to claim 1, wherein a method for obtaining the actual depths comprises using a TEM to scan the first wafer.

3. The method for monitoring the word line according to claim 1, wherein the first wafer and the second wafer are from a same batch of wafers.

4. The method for monitoring the word line according to claim 3, wherein θ of the first word lines in the local region of the first wafer are the same as each other.

5. The method for monitoring the word line according to claim 1, wherein before performing the electron beam scanning on the first wafer, the method further comprises:
performing regional positioning processing on an image of the first wafer to define a plurality of active regions, a plurality of isolation structure regions, and a plurality of word line regions corresponding to the first word lines; and
defining a region where the word line region overlaps with the active region as a first region, and defining a region where the word line region overlaps with the isolation structure region as a second region.

6. The method for monitoring the word line according to claim 5, wherein after defining the first region and the second region and before performing the electron beam scanning on the first wafer, the method further comprises:
providing a first test wafer, a second test wafer, and a third test wafer, wherein word line depths of the first test wafer, the second test wafer, and the third test wafer are different from each other;
respectively performing the electron beam scanning on the first test wafer, the second test wafer, and the third test wafer to obtain a plurality of respective test DIs;
respectively performing optical scanning on the first test wafer, the second test wafer, and the third test wafer to obtain a plurality of respective average depths;
calculating an R² value of the test DIs and the average depths of the first test wafer, the test DIs and the average depths of the second test wafer, and the test DIs and the average depths of the third test wafer via regression analysis, and confirming that the R² value is not less than 0.9.

7. The method for monitoring the word line according to claim 5, further comprising:
performing linear regression analysis on the first DIs and the actual depths in all the first regions or the second regions in the local region of the first wafer to obtain, obtaining a first linear regression equation between the first DIs and the actual depths, and obtaining a slope S.

8. The method for monitoring the word line according to claim 7, wherein the slope S is not less than 0.9, and the word line depths of the second wafer are monitored according to the first linear regression equation and the second DIs of the second wafer.

9. The method for monitoring the word line according to claim 7, wherein the slope S is less than 0.9, and the method for monitoring the word line further comprises:
obtaining a plurality of third DIs according to θ obtained by performing the electron beam scanning on the first wafer, SP and W of each of the first word lines in all the first regions or the second regions in the local region of the scanned first wafer, and Equation (1);
performing linear regression analysis on the third DIs and the actual depths in all the first regions or the second regions in the local region of the first wafer, and obtaining a second linear regression equation between the third DIs and the actual depths; and
monitoring the word line depths of the second wafer according to the second linear regression equation and the second DIs of the second wafer.
